(19) United States
(12) Patent Application Publication
(10) Pub. No.: US 2016/0064603 A1
(43) Pub. Date: Mar. 3, 2016

(54) Light Emitting Diodes With Current Confinement

(71) Applicant: Toshiba Corporation, Tokyo (JP)

(72) Inventors: Chao-Kun Lin, San Jose, CA (US); Wei Zhao, Dublin, CA (US)

(21) Appl. No.: 14/468,831

(22) Filed: Aug. 26, 2014

(51) Int. Cl. H01L 33/14; H01L 33/62

(52) U.S. Cl. CPC H01L 33/145; H01L 33/62

(57) ABSTRACT

A light emitting diode (LED) assembly with a current blocking layer along the periphery of the LED is disclosed. In one embodiment, the LED assembly includes an LED comprising a light emitting layer disposed between a first layer having a first conductivity type and a second layer having a second conductivity type. The LED assembly further includes a contact electrically coupled to the first layer and a current blocking layer formed along a periphery of the LED at an interface with the contact, and covering a peripheral portion of the first contact. The current blocking layer forms a non-ohmic connection with the contact, thereby limiting the current injection between the contact and the first layer of the LED. In one embodiment, the current blocking layer surrounds a portion of the first layer, defining a portion of the light emitting layer that emits photons. In one embodiment, the current blocking layer comprises a transparent insulating layer between the LED and the contact. In one embodiment, the current blocking layer comprises a plasma treated region of the first layer of the LED.

### FIELD OF THE INVENTION

This invention generally relates to light emitting diode (LED) assemblies, and more particularly, to LED assemblies with current confinement along the periphery of the LED.

### BACKGROUND OF THE INVENTION

In general, light emitting diodes (LEDs) begin with a semiconductor growth substrate, generally a group III-V compound such as gallium nitride (GaN), gallium arsenide (GaAs), gallium phosphide (GaP), indium phosphide (InP), and gallium arsenide phosphide (GaAsP). The semiconductor growth substrate may also be sapphire (Al₂0₃), silicon (Si), and silicon carbide (SiC) for group III-Nitride based LEDs, such as gallium nitride (GaN). Epitaxial semiconductor layers are grown on the semiconductor growth substrate to form the N-type and P-type semiconductor layers of the LED. The epitaxial semiconductor layers may be formed by a number of developed processes including, for example, Liquid Phase Epitaxy (LPE), Molecular-Beam Epitaxy (MBE), and Metal Organic Chemical Vapor Deposition (MOCVD). After the epitaxial semiconductor layers are formed, electrical contacts are coupled to the N-type and P-type semiconductor layers using known photolithography, etching, evaporation, and polishing processes. Individual LED chips are diced and mounted to a package with wire bonding. An encapsulant is deposited onto the LED chip and the LED chip is sealed with a protective lens which also aids in light extraction.

There are a number of different types of LED assemblies, including lateral LEDs, vertical LEDs, flip-chip LEDs, and hybrid LEDs (a combination of the vertical and flip-chip LED structure). Typically, vertical LED, flip-chip LED, and hybrid LED assemblies utilize a reflective contact between the LED and the underlying substrate or submount to reflect photons which are generated downwards toward the substrate or submount. By using a reflective contact, more photons are allowed to escape the LED rather than be absorbed by the substrate or submount, improving the overall light output power and light output efficiency of the LED assembly.

Another improvement to the light output efficiency of LED assemblies is shown in FIGS. 1A and 1B, and is described in U.S. Patent Publication No. 2009/0242929 (“Lin”), incorporated herein by reference. FIG. 1A is a plan view of the vertical LED assembly 100 according to Lin. In FIG. 1A, vertical LED assembly 100 has a second contact 108 electrically coupled to the second semiconductor layer 101 of the LED 102. Below the LED 102 is a reflective first contact 106. The first contact 106 is surrounded by a barrier metal 104. FIG. 1B is a corresponding cross-sectional view of the vertical LED assembly 100 along axis AA shown in FIG. 1A. In FIG. 1B, LED 102 is bonded to substrate 112. A bonding metal layer 110 and a barrier metal layer 104 surround the first contact 106. A current blocking region 109 is formed with a portion aligned with the second contact 108, between the second semiconductor layer 101 of LED 102 and the first contact 106.

During device operation, the current blocking region 109 limits current injection between the first contact 106 and the second contact 108, thereby reducing photon generation directly underneath the second contact 108. By reducing the photon generation underneath the second contact 108, fewer photons will be absorbed by the second contact 108, and thus, the overall light output efficiency of the vertical LED assembly 100 will be improved.

FIG. 1C is an expanded cross-sectional view of the vertical LED assembly 100 corresponding to area BB shown in FIG. 1B. In FIG. 1C, the first contact 106 is surrounded by the barrier metal layer 104. As previously discussed, the contact between the LED and the underlying substrate or submount package typically comprises a highly-reflective material. For most modern LED manufacturers, silver (Ag) is the most common material used for reflective first contact 106, due to its high optical reflectivity (greater than 90% in the visible wavelength range) compared to other available metals. However, silver (Ag) is known for its notorious electro-migration characteristic, and will eventually form a conductive short path when silver (Ag) is exposed to the atmosphere, leading to device failure. To prevent electro-migration of the silver (Ag) first contact 106, the first contact 106 is completely surrounded, or encapsulated, by the barrier metal layer 104 and the first semiconductor layer 103 to isolate the first contact 106 from the atmosphere.

The barrier metal layer 104 usually comprises a material which is less reflective than the silver (Ag) first contact 106. Typically, the barrier metal layer 104 materials have an optical reflectivity of less than 80% in the visible wavelength range. Common barrier metal layer 104 materials include platinum (Pt), gold (Au), titanium (Ti), tungsten (W), nickel (Ni), titanium-tungsten alloy (TiW), and molybdenum (Mo). The barrier metal layer 104 does not form an ohmic connection with the P-type semiconductor layer 103. During device operation, current injection primarily occurs in the region above the first contact 106. Due to the internal reflection of the LED 102, photons 111 which are generated from the active region 105, near the edge of the first contact 106, may be internally reflected by the LED 102 and absorbed by the less reflective barrier metal layer 104. In short, the overall light output power and light output efficiency of the vertical LED assembly 100 disclosed by Lin is reduced.

There is, therefore, an unmet demand for LED assemblies with reduced internal photon absorption and improved light output power and light output efficiency.

### BRIEF DESCRIPTION OF THE INVENTION

In one embodiment, a light emitting diode (LED) assembly includes an LED comprising a light emitting layer disposed between a first layer having a first conductivity type and a second layer having a second conductivity type. In one embodiment, the first layer is initially of a P-type doping, and the second layer is initially of an N-type doping. In another embodiment, the first layer is initially of an N-type doping, and the second layer is initially of a P-type doping. The LED assembly further includes a first contact electrically coupled to the first layer and a first current blocking layer along a periphery of the LED at an interface with the first contact, and covering a peripheral portion of the first contact. The first current blocking layer forms a non-ohmic connection with the first contact, thereby limiting the current injection between the first contact and the first layer of the LED.

In one embodiment, the first contact comprises silver (Ag). In one embodiment, the first current blocking layer extends up to 50 μm inward of an upper lateral side edge of the first contact. In another embodiment, the first current blocking layer extends up to 50 μm inward of each of the upper lateral side edges of the first contact. In another embodiment, the first current blocking layer surrounds a portion of the first layer, defining a portion of the light emitting layer that emits photons.

In one embodiment, the first current blocking layer is between the LED and the first contact. In one embodiment, the first current blocking layer comprises a transparent insulating layer disposed between the first contact and the first layer of the LED. In one embodiment, the transparent insulating layer comprises SiO₂. In other embodiments, the transparent insulating layer can be Si₃N₄, Al₂O₃, TiO₂, or any other suitable dielectric material.

In another embodiment, the first current blocking layer is formed in the first layer of the LED. In one embodiment, the first current blocking layer is a plasma treated region of the first layer. In one embodiment, the plasma treatment compensates a doping concentration of the treated region of the first layer of the LED, forming a non-ohmic connection between the treated region of the first layer of the LED and the first contact. In another embodiment, the plasma treatment converts the conductivity type of the treated region of the first layer to the opposite conductivity type, forming a non-ohmic connection between the treated region of the first layer of the LED and the first contact. In one embodiment, the plasma treatment uses a gas including oxygen (O₂), nitrogen (N₂), hydrogen (H₂), argon (Ar), helium (He), neon (Ne), krypton (Kr), xenon (Xe) or any combination thereof.

In one embodiment, the LED assembly further includes a second contact electrically coupled to the second layer of the LED, and a second current blocking layer having a portion substantially aligned with the second contact at an interface with the LED and the first contact. The second current blocking layer forms a non-ohmic connection with the first contact, thereby limiting the current injection between the first contact and the first layer of the LED.

In one embodiment, the LED assembly is a vertical LED assembly with a substrate bonded to the LED and the first contact is disposed between the LED and the substrate. In another embodiment, the LED assembly is a flip-chip LED assembly with a submount bonded to the LED and the first contact is disposed between the LED and the submount. In one embodiment, The flip-chip LED assembly further includes a first and second interconnects electrically coupled to the first contact and the second layer of the LED, respectively. A third and fourth interconnects are attached to the submount, and the first and third interconnects and the second and fourth interconnects are electrically coupled.

### BRIEF DESCRIPTION OF THE FIGURES

FIG. 1A shows a plan view of a vertical LED assembly in the prior art.

FIG. 1B shows a cross-sectional view of the vertical LED assembly of FIG. 1A.

FIG. 1C shows an expanded cross-sectional view of the vertical LED assembly of FIG. 1B.

FIG. 2A shows a plan view of a vertical LED assembly with a current blocking layer along the periphery of the LED, according to one embodiment of the invention.

FIG. 2B shows a cross-sectional view of the vertical LED assembly of FIG. 2A.

FIG. 2C shows an expanded cross-sectional view of the vertical LED assembly of FIG. 2B.

FIG. 3A shows a plan view of a flip-chip LED assembly with a current blocking layer along the periphery of the LED, according to one embodiment of the invention.

FIG. 3B shows a cross sectional view of the flip-chip LED assembly of FIG. 3A.

FIG. 4 shows a comparison between the light intensity of an LED assembly with a current blocking layer along the periphery of the LED and the light intensity of an LED assembly without the current blocking layer, according to one embodiment of the invention.

FIG. 5A shows a plot of the light output power of various LED assemblies as a function of the width of the current blocking layer along the periphery of the LED assembly operating at 100 mA of current, according to one embodiment of the invention.

FIG. 5B shows a plot of the wall-plug efficiency of various LED assemblies as a function of the width of the current blocking layer along the periphery of the LED assembly operating at 100 mA of current, according to one embodiment of the invention.

FIG. 6A shows a plot of the light output power of various LED assemblies as a function of the width of the current blocking layer along the periphery of the LED assembly operating at 350 mA of current, according to one embodiment of the invention.

FIG. 6B shows a plot of the wall-plug efficiency of various LED assemblies as a function of the width of the current blocking layer along the periphery of the LED assembly operating at 350 mA of current, according to one embodiment of the invention.

FIG. 7 shows a plot of the wall-plug efficiency of an LED assembly with a current blocking layer along the periphery of the LED as a function of the operating current, according to one embodiment of the invention.

FIG. 8 shows a plot of the external quantum efficiency of an LED assembly with a current blocking layer along the periphery of the LED as a function of the operating current, according to one embodiment of the invention.

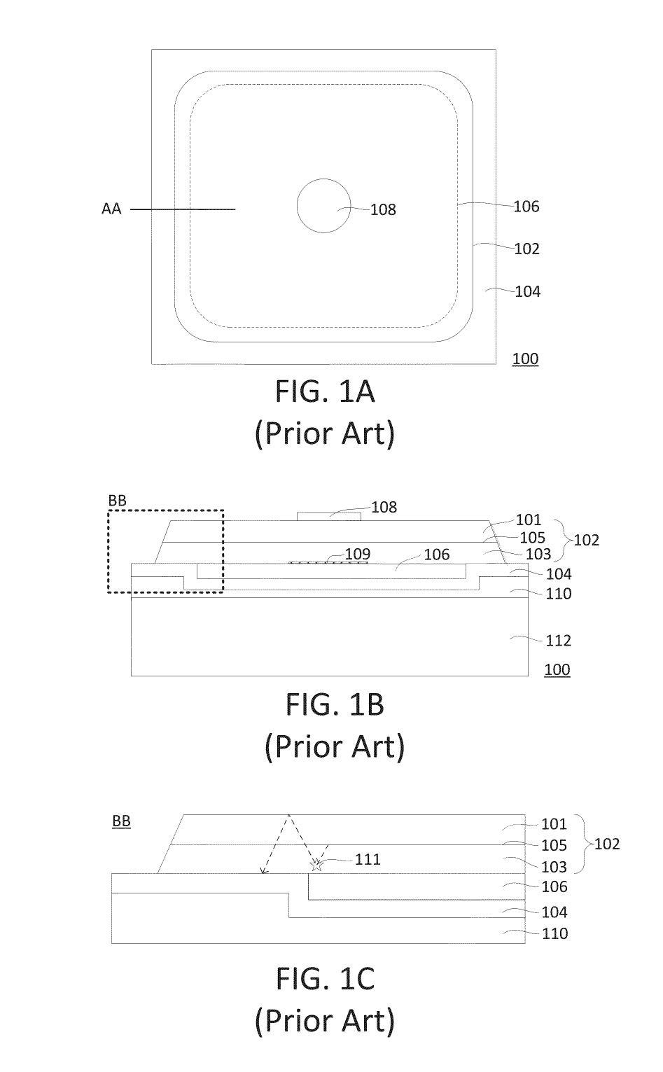

### DETAILED DESCRIPTION OF THE INVENTION

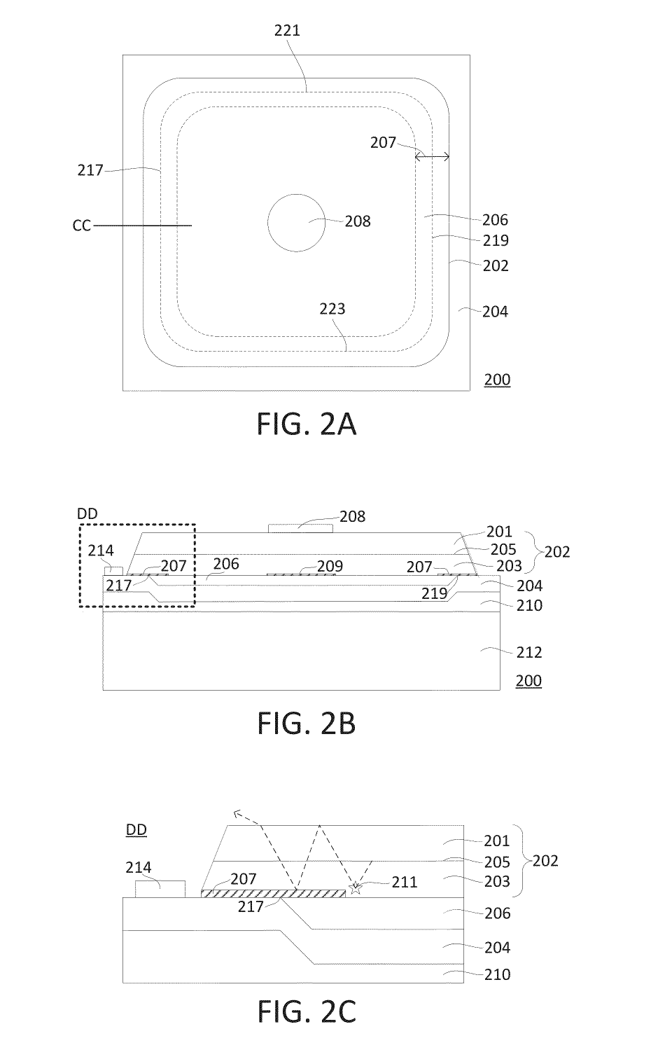

FIG. 2A shows a plan view of a vertical LED assembly 200 with a current blocking region 207 along the periphery of the LED, according to one embodiment of the invention. In FIG. 2A, a current blocking layer 207 is formed at an interface between a first contact 206 and the LED 202, and extends along the periphery of the LED 202 and inward of upper lateral side edges 217, 219, 221, and 223 of the first contact 206, covering a portion of the perimeter of the first contact 206. While the current blocking layer 207 as shown in FIG. 2A is formed surrounding the periphery of the LED 202 and covers a portion of the perimeter of the first contact 206, in other embodiments the current blocking region 207 need not be continuous and may cover only a portion of upper lateral side edges 217, 219, 221, and/or 223 of the first contact 206.

A metal barrier layer 204 surrounds the first contact 206, and along with the LED 202, isolates or encapsulates the first contact 206 from the atmosphere. In one embodiment, the first contact 206 comprises silver (Ag). In one embodiment, the current blocking layer 207 extends up to 50 μm inward of the lateral side edge 217 of the first contact 206. In another embodiment, the current blocking layer 207 extends up to 50 μm inward of each lateral side edge 217, 219, 221, and 223 of the first contact 206.

FIG. 2B shows a cross-sectional view of the vertical LED assembly 200 of FIG. 2A. In FIG. 2B, the cross-sectional view is taken along the axis CC, shown in FIG. 2A. As shown in FIG. 2B, LED 202 is bonded to substrate 212. In one embodiment, the first semiconductor layer 203 is of a P-type, and the second semiconductor layer 201 is of an N-type. In another embodiment, the first semiconductor layer 203 is of an N-type, and the second semiconductor layer 201 is of a P-type. A bonding metal layer 210 and a barrier metal layer 204 surrounds the first contact 206. A current blocking layer 207 is formed at an interface of the first semiconductor layer 203 of LED 202 and the first contact 206, along the periphery of the LED 202. The current blocking layer 207 forms a non-ohmic connection between the first semiconductor layer 203 and the first contact 206. The non-ohmic connection forms an electrical junction between the first semiconductor layer 203 and the first contact 206 that does not demonstrate linear I-V characteristics. The current blocking layer 207 extends inward of the upper lateral side edges 217 and 219 of the first contact 206, covering a portion of the perimeter of the first contact 206.

During device operation, current injection between the first contact 206 and the first semiconductor layer 203 is restricted due to the non-ohmic connection formed by the current blocking layer 207, thereby limiting photon generation near the edges of the first semiconductor layer 203.

In one embodiment, the current blocking layer 207 comprises a transparent (optically lossless) insulating layer, such as SiO₂. In other embodiments, the current blocking layer 207 may comprise Si₃N₄, Al₂O₃, TiO₂, or any other suitable dielectric material. In this embodiment, the current blocking layer 207 is formed by using known photolithography and etching processes form a layer of SiO₂ between the surfaces of the first semiconductor layer 203 and the first contact 206.

In another embodiment, the current blocking layer 207 comprises a plasma-treated region of the first semiconductor layer 203 where the ion-bombardment from the plasma treatment compensates a doping concentration of the first semiconductor layer 203 or converts the treated current blocking layer 207 of the first semiconductor layer 203 to the opposite conductivity type. In one embodiment, the plasma treatment uses gases including oxygen (O₂), nitrogen (N₂), hydrogen (H₂), argon (Ar), helium (He), neon (Ne), krypton (Kr), xenon (Xe) or any combination thereof.

For example, the first semiconductor layer 203 is initially of a P-type. After plasma treatment, the current blocking layer 207 of the first semiconductor layer 203 has an N-type doping. By converting the current blocking layer 207 of the first semiconductor layer 203 to N-type, or compensating the doping concentration of the first semiconductor layer 203, the current blocking layer 207 forms a non-ohmic connection, limiting the current injection between the first contact 206 and the first semiconductor layer 203.

By limiting the photon generation near the edges of the less reflective barrier metal layer 204, photons generated at the boundary between the first contact 206 and the current blocking layer 207 will have an increased chance of escaping the LED 202 without experiencing any optical loss from the barrier metal layer 204, even if initially internally reflected, thus improving the overall light output power and light output efficiency of the vertical LED assembly 200.

FIG. 2C shows an expanded cross-sectional view of the vertical LED assembly 200 of FIG. 2B. In FIG. 2C, during device operation, photons 211 generated from the active region 205, near the boundary between the first contact 206 and the current blocking layer 207, may be internally reflected by the LED 202. Because the current blocking layer 207 is optically lossless, according to one embodiment of the invention, photons 211 will be reflected back by the first contact 206, and provided another chance to escape the LED 202 as emitted light. As shown in FIGS. 2A-C, the effective light emitting area of the LED 202 is smaller than the area of the first contact 206, due to the current blocking layer 207 around the periphery of the LED 202 and extending inward of the edges of the first contact 206. Despite the reduction of the light emitting area of the LED 202, unexpectedly the overall light output power and light output efficiency of the vertical LED assembly 200 is still improved due to the reduced likelihood of optical loss experienced by generated photons 211 as a result of the current blocking layer 207. Indeed, this result is counter intuitive given the reduced light emitting area of the LED 202.

Optionally, the vertical LED assembly 200 may be further improved by forming a second current blocking layer 209 at the interface between the first contact 206 and the LED 202. In one embodiment, the second current blocking layer 209 is aligned with the second contact 208, with the current blocking layer 209 below the second contact 208. In another embodiment, the second current blocking layer 209 is substantially aligned with the second contact 208, with only a portion of the second current blocking layer 209 below the second contact 208. By incorporating both the current blocking layer 207 and the second current blocking layer 209, the vertical LED assembly 200 minimizes the likelihood of photon absorption by both the barrier metal layer 204 and the second contact 208, thus improving the overall light output power and light output efficiency of the vertical LED assembly 200.

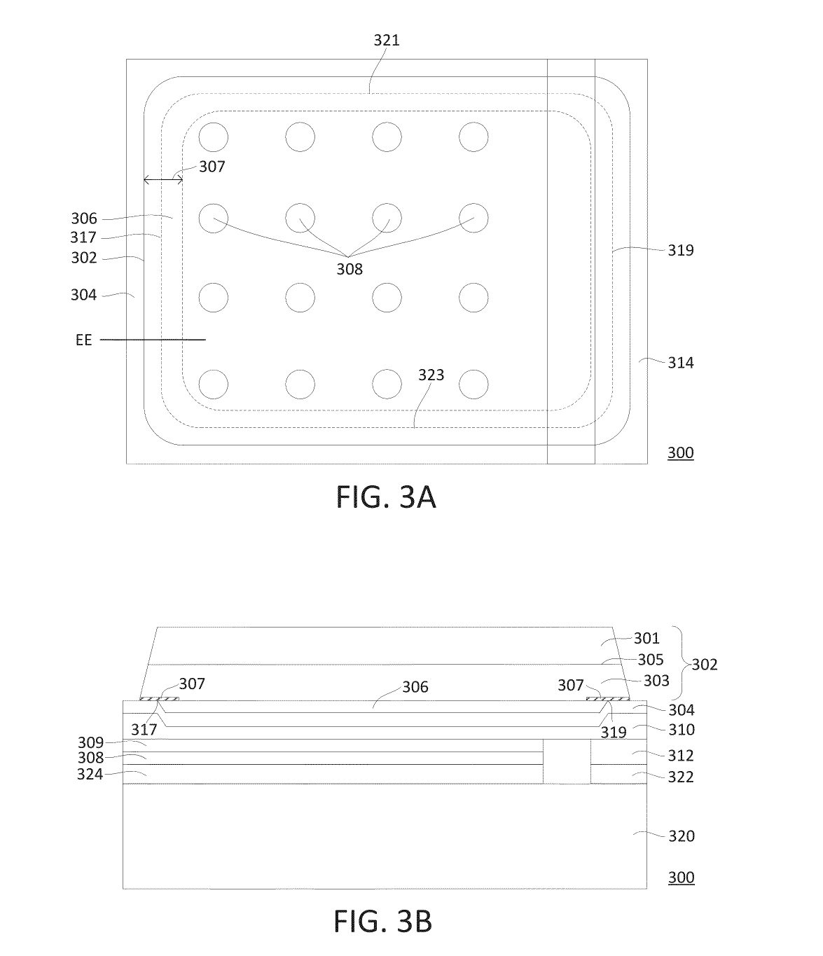

FIG. 3A shows a plan view of a flip-chip LED assembly 300 with a current blocking layer 307 along the periphery of the LED 302, according to one embodiment of the invention. The plan view of the flip-chip LED assembly 300 shown in FIG. 3A is shown without the submount. In FIG. 3A, the current blocking layer 307 is formed between the first contact 306 and the LED 302, and extends along the periphery of the LED 302 and inward of the upper lateral side edges 317, 319, 321, and 323 of the first contact 306, covering a portion of the perimeter of the first contact 306. While the current blocking layer 307 as shown in FIG. 3A is formed surrounding the periphery of the LED 302 and covers a portion of the perimeter of the first contact 306, in other embodiments the current blocking region 307 need not be continuous and may cover only a portion of upper lateral side edges 317, 319, 321, and/or 323 of the first contact 306.

A metal barrier layer 304 surrounds the first contact 306, and along with the LED 302, isolates or encapsulates the first contact 306 from the atmosphere. In one embodiment, the first contact 306 comprises silver (Ag). In one embodiment, the current blocking layer 307 extends between up to 50 μm inward of the upper lateral side edge 317 of the first contact 306. In another embodiment, the current blocking layer 307 extends between up to 50 μm inward of each lateral side edge 317, 319, 321, and 323 of the first contact 306.

FIG. 3B shows a cross sectional view of the flip-chip LED assembly 300 of FIG. 3A. In FIG. 3B, the cross-sectional view is taken along the axis EE, shown in FIG. 3A. As shown in FIG. 3B, the LED 302 is bonded to submount 320 by bonding third and fourth interconnects 322 and 324 of the submount 320 to the first interconnect 312 and the second interconnect 308, respectively. The first interconnect 312 is electrically coupled to the first contact 306, barrier metal layer 304, and bonding metal layer 310. The second interconnect 308 is electrically coupled to the second semiconductor layer 301 (not shown). The second interconnect 308 is electrically isolated from the first interconnect 312 by passivation layer 309.

In another embodiment, the submount 320 is directly bonded to the LED 302 with the third interconnect 322 electrically coupled to the first semiconductor layer 303 and the fourth interconnect 324 electrically coupled to the second semiconductor layer 301 (not shown). In one embodiment, the first semiconductor layer 303 is of a P-type, and the second semiconductor layer 301 is of an N-type. In another embodiment, the first semiconductor layer 303 is of an N-type, and the second semiconductor layer 301 is of a P-type.

Current blocking layer 307 is formed at an interface of the first semiconductor layer 303 of LED 302 and the first contact 306, along the periphery of the LED 302. The current blocking layer 307 forms a non-ohmic connection between the first semiconductor layer 303 and the first contact 306. The non-ohmic connection forms an electrical junction between the first semiconductor layer 303 and the first contact 306 that does not demonstrate linear I-V characteristics. The current blocking layer 307 extends inward of the upper lateral side edges 317 and 319 of the first contact 306, covering a portion of the perimeter of the first contact 306.

As previously explained, during device operation, current injection between the first contact 306 and the first semiconductor layer 303 is limited due to the non-ohmic connection formed by the current blocking layer 307, thereby limiting photon generation near the edges of the first semiconductor layer 303.

In the same manner as previously explained in relation to the embodiment corresponding to FIGS. 2A-C, the current blocking layer 307 comprises a transparent (optically lossless) insulating layer, such as SiO₂, Si₃N₄, Al₂O₃, TiO₂, or any other suitable dielectric material. In another embodiment, the current blocking layer 307 comprises a plasma-treated region of the first semiconductor layer 303. By limiting the photon generation near the edges of the less reflective barrier metal layer 304, photons generated at the boundary between the first contact 306 and the current blocking layer 307 will have an increased chance of escaping the LED 302 without experiencing any optical loss from the barrier metal layer 304, thus unexpectedly improving the overall light output power and light output efficiency of the flip-chip LED assembly 300.

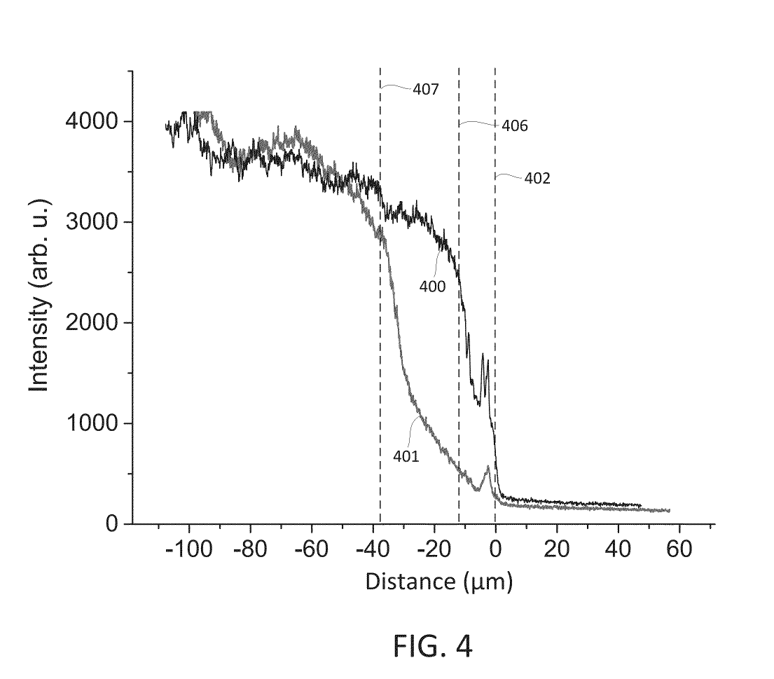

FIG. 4 shows a comparison between the light intensity of an LED assembly with a current blocking layer along the periphery of the LED and the light intensity of an LED assembly without such current blocking layer, according to one embodiment of the invention. In FIG. 4, light intensity plot 401 represents the light intensity of an LED assembly with a current blocking layer along the periphery of the LED, and light intensity plot 400 represents the light intensity of an LED assembly without such current blocking layer. The current blocking layer 407 begins at a distance of approximately 38 μm inwards of the edge of the LED 402 (represented as the reference point 0 μm along the x-axis), and the first contact 406 extends to a distance of approximately 12 μm inwards of the edge of the LED 402, effectively creating a current blocking layer extending approximately 26 μm inward of an upper lateral edge 406 of the first contact.

Because the current blocking layer 407 limits the generation of photons some distance away from barrier metal layer 404, photons generated near the edge of the current blocking layer 407 have an increased likelihood of escaping the LED 402 without being absorbed by the barrier metal layer 404. As shown in FIG. 4, light intensity plot 401 drops to almost an insignificant amount in the barrier metal layer 404 due to photons being generated away from the barrier metal layer 404 and escaping the LED before reaching the barrier metal layer 404. In contrast, light intensity plot 400 shows a very steep drop in light intensity in the barrier metal layer 404, between the edge of the first contact 406 and the edge of the LED 402, indicating strong optical absorption of the photons generated at the edge of the first contact 406 by the barrier metal layer 404. As both light intensity plot 401 and 400 approach the edge 402 of the LED, both drop off towards 0 as the layer between the first contact edge 406 and the LED edge 402 comprises the barrier metal layer which forms a non-ohmic connection with the LED, limiting the current injection and consequent photon generation in this layer.

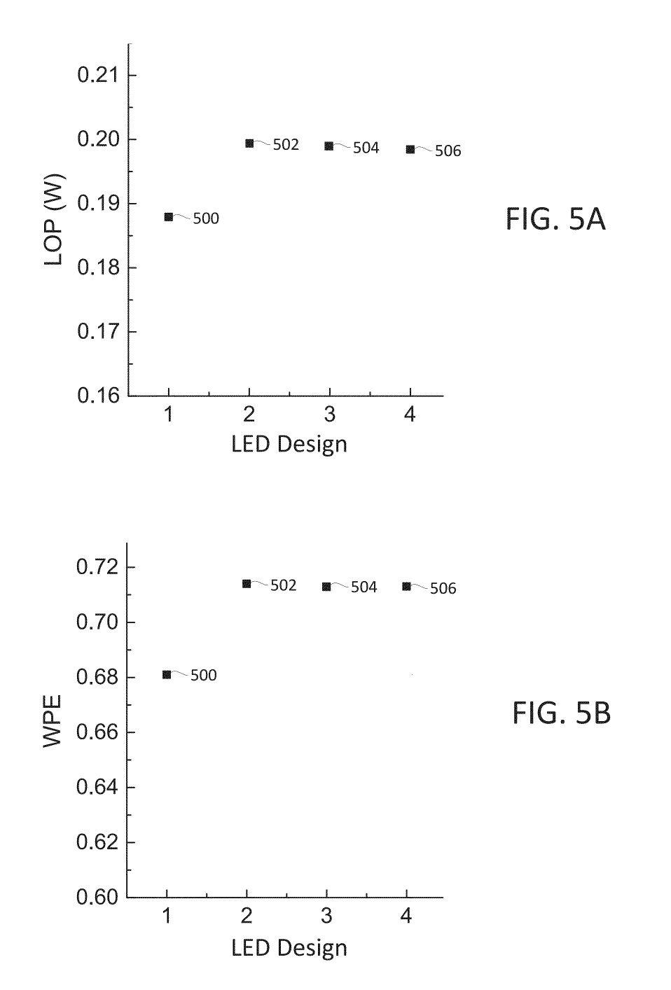

FIG. 5A shows a plot of the light output power of various LED assemblies as a function of the width of the current blocking layer along the periphery of the LED assembly operating at 100 mA of current, according to one embodiment of the invention. Data point 500 represents an LED assembly without a current blocking layer along the periphery of the LED. Data point 502 represents an LED assembly with a current blocking layer along the periphery of the LED, and extending 26 μm inward of the upper lateral side edges of the first contact. Data points 504 and 506 represent LED assemblies with current blocking layers extending 19 μm and 12 μm inward of the upper lateral side edges of the first contact, respectively.

As shown in FIG. 5A, the light output power of certain LED assemblies will benefit from a wider current blocking layer that extends further inward of an edge of the first contact, though all LED assemblies with a current blocking layer along the periphery of the LED 502, 504, and 506 have improved light output power compared to the LED assembly without a current blocking layer 500. In general, the light output power of all LED assemblies are improved by approximately 6-9% at 100 mA of power by using a current blocking layer along the periphery of the LED, at an interface of the first contact and the LED.

FIG. 5B shows a plot of the wall-plug efficiency of various LED assemblies as a function of the width of the current blocking layer along the periphery of the LED assembly operating at 100 mA of current, according to one embodiment of the invention. The wall-plug efficiency of an LED assembly represents the energy conversion efficiency with which the LED assembly converts electrical power into optical power. Again, data point 500 represents an LED assembly without a current blocking layer along the periphery of the LED, and data points 502, 504, and 506 represents LED assemblies with current blocking layers extending 26 μm, 19 μm, and 12 μm inward of the upper lateral side edges of the first contact, respectively. As shown in FIG. 5B, the increase in wall-plug efficiency generally tracks the increase in light output power seen in FIG. 5A, with the greatest improvement observed by the LED assembly 502 with a current blocking layer extending 26 μm inward of the upper lateral side edges of the first contact, and with the wall-plug efficiency of all LED assemblies realizing a 5-7% improvement at 100 mA of power by using a current blocking layer along the periphery of the LED, at an interface of the first contact and the LED.

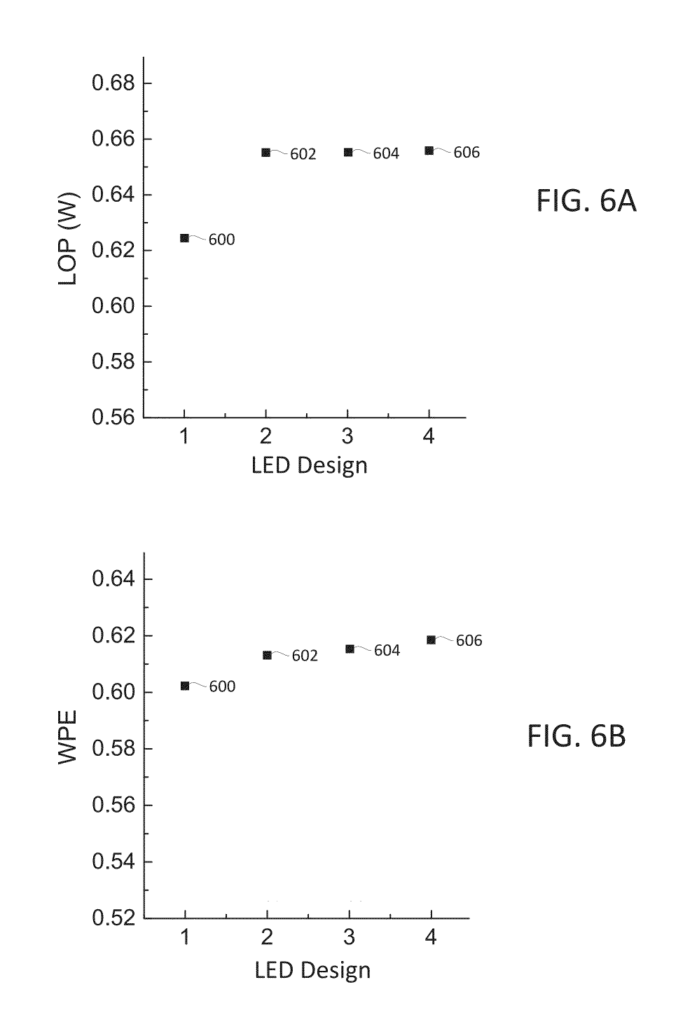

FIG. 6A shows a plot of the light output power of various LED assemblies as a function of the width of the current blocking layer along the periphery of the LED assembly operating at 350 mA of current, according to one embodiment of the invention. Like FIG. 5A, data point 600 represents an LED assembly without a current blocking layer along the periphery of the LED, and data points 602, 604, and 606 represents LED assemblies with current blocking layers extending 26 μm, 19 μm, and 12 μm inward of the upper lateral side edges of the first contact, respectively. In general, the light output power of all LED assemblies 602, 604, and 606 with a current blocking layer along the periphery of the LED are improved by approximately 5-7% at 350 mA, a slight reduction in improvement compared to FIG. 5A.

This reduction in overall light output power is a result of current crowding. At low power, current distribution within the LED is uniform, thereby generating photons in a generally uniform manner throughout the LED. At high power, the current density within the LED begins to crowd, with increasing current concentration focused around the electrical contacts. As a result, fewer photons are generated at the edges of the LED and thus, fewer photons which will be absorbed by the less reflective barrier metal that surrounds the first contact. The greater the degree of current crowding, the smaller the improvement achieved with a current blocking layer along the periphery of the LED.

FIG. 6B shows a plot of the wall-plug efficiency of various LED assemblies as a function of the width of the current blocking layer along the periphery of the LED assembly operating at 350 mA of current, according to one embodiment of the invention. Again, data point 600 represents an LED assembly without a current blocking layer along the periphery of the LED, and data points 602, 604, and 606 represents LED assemblies with current blocking layers extending 26 μm, 19 μm, and 12 μm inward the upper lateral side edges of the first contact, respectively. As shown in FIG. 6B, the increase in wall-plug efficiency is realized by the LED assembly 606 with a narrower current blocking region than the LED assembly 602 with a wider current blocking region, however, in general the wall-plug efficiency of all LED assemblies 602, 604, and 606 only realize a 2-3% improvement at 350 mA of power by using a current blocking layer along the periphery of the LED, due to the current crowding effects and the increased voltage required to operate the LED assembly at 350 mA of current offsetting the benefit of the current blocking layer at higher operating currents, as previously explained. Generally, LED assemblies operating at higher currents will see little to no improvement by forming a current blocking layer along the periphery of the LED at an interface of the first contact and the LED.

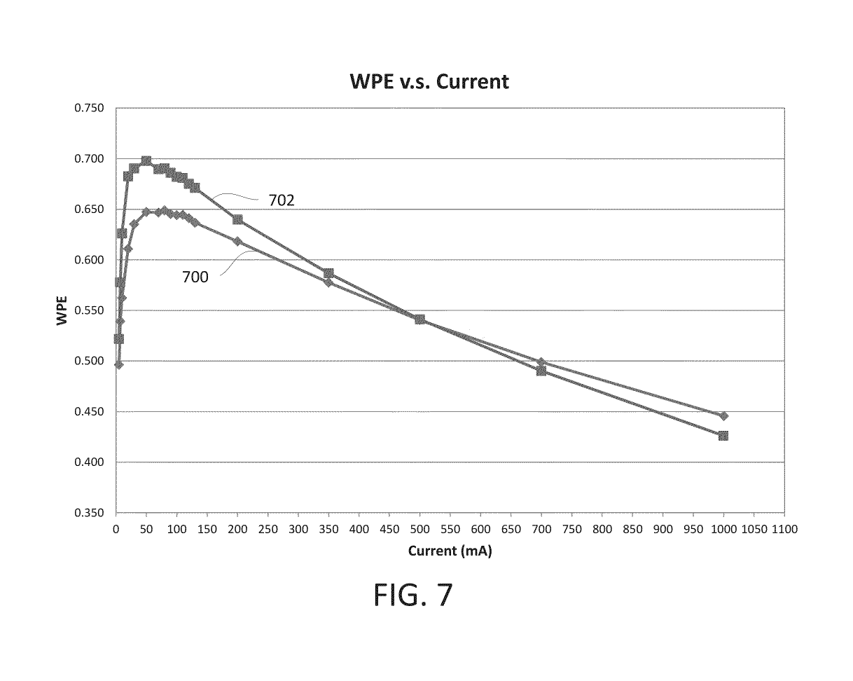

FIG. 7 shows a plot of the wall-plug efficiency of an LED assembly with a current blocking layer along the periphery of the LED as a function of the operating current, according to one embodiment of the invention. In FIG. 7, an LED assembly 702 has a current blocking layer along the periphery of the LED that extends 26 μm inward of the upper lateral side edges of the first contact. A reference LED assembly 700 without a current blocking layer along the periphery of the LED is also shown as reference.

As shown in FIG. 7, the greatest improvement in wall-plug efficiency is realized at low operating currents, particularly between 25 mA to 175 mA. At operating currents above 500 mA, the wall-plug efficiency of the LED assembly 702 with the current blocking layer is worse than the wall-plug efficiency of the reference LED assembly 700 without the current blocking layer due to the current crowding effects and the increased voltage required to generate higher operating currents. At higher currents, the wall-plug efficiency will benefit from a greater first contact area for increased current injection, and thus, the current blocking layer will have a negative impact during high current operation of the LED assembly.

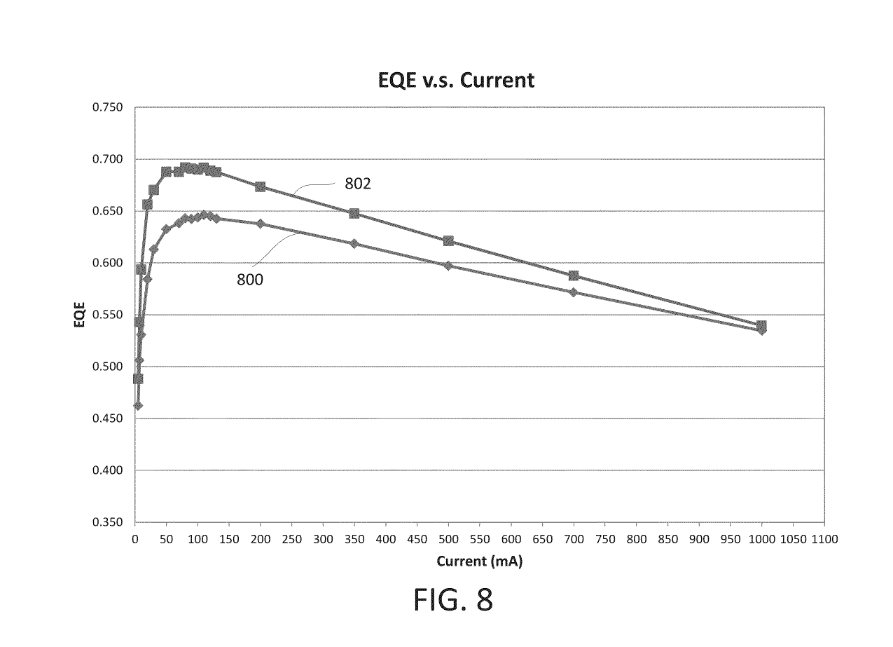

FIG. 8 shows a plot of the external quantum efficiency of an LED assembly with a current blocking layer along the periphery of the LED as a function of the operating current, according to one embodiment of the invention. The external quantum efficiency of the LED assembly corresponds to how efficiently the LED assembly converts injected carriers into photons that escape the LED as light. In effect, it is represented by the following ratio:

$$External Quantum Efficiency = \frac{\# of Photons Emitted}{\# of Carriers Injected}$$

In FIG. 8, an LED assembly 802 has a current blocking layer along the periphery of the LED that extends 26 μm inward the upper lateral side edges of the first contact. A reference LED assembly 800 without a current blocking layer along the periphery of the LED is also shown as reference. As shown in FIG. 8A, the greatest improvement in external quantum efficiency of the LED assembly 802 is realized at low operating currents, particularly between 25 mA to 200 mA. At higher currents, current crowding effects and internal quantum efficiency droop reduce the overall external quantum efficiency of the LED 802, as injected carriers are focused around the electrical contacts, away from the periphery of the LED. At an operating current of 1 A, the LED assembly 802 has effectively the same external quantum efficiency as the reference LED assembly 800.

As shown by FIGS. 5A-B, 6A-B, 7=, and 8, optimization of the wall-plug efficiency and external quantum efficiency of any given LED assembly with a current blocking layer along the periphery of the LED will depend on the operating conditions. At lower operating currents, an LED assembly with a wider current blocking layer that extends further inward the edges of the first contact may exhibit superior efficiency over an LED assembly with narrower current blocking layers, or no current blocking layer at all. Conversely, at high operating currents, an LED assembly with no current blocking layer along the periphery of the LED will be most efficient. Thus, the width of the current blocking layer along the periphery of the LED should be optimized for the specific LED assembly design and expected operating conditions.

While FIGS. 5A-B, 6A-B, 7, and 8 illustrate the improvement of LED assemblies having current blocking layers with widths extending 12 μm, 19 μm, and 26 μm inwards of the upper lateral side edges of the first contact, the present invention is not limited to only current blocking layers with these widths. A person having ordinary skill in the art would recognize, given this disclosure, that other current blocking layer widths (both larger and smaller) may result in the same unexpected improvement in light output power, external quantum efficiency, and wall-plug efficiency.

Other objects, advantages and embodiments of the various aspects of the present invention will be apparent to those who are skilled in the field of the invention and are within the scope of the description and the accompanying Figures. For example, but without limitation, structural or functional elements might be rearranged consistent with the present invention. Similarly, principles according to the present invention could be applied to other examples, which, even if not specifically described here in detail, would nevertheless be within the scope of the present invention.

What is claimed is:

1. A light emitting diode (LED) assembly comprising:
an LED comprising a light emitting layer disposed between a first layer having a first conductivity type and a second layer having a second conductivity type;
a first contact electrically coupled to the first layer; and
a first current blocking layer formed along a periphery of the LED at an interface with the first contact and covering a peripheral portion of the first contact.

2. The LED assembly of claim 1 wherein the first contact comprises a material having an optical reflectivity greater than 80%.

3. The LED assembly of claim 1 wherein the first contact comprises Ag.

4. The LED assembly of claim 1 further comprising:
a second contact electrically coupled to the second layer; and
a second current blocking layer having a portion substantially aligned with the second contact at an interface with the LED and the first contact, wherein a non-ohmic connection is formed between the second current blocking layer and the first contact.

5. The LED assembly of claim 1 wherein a non-ohmic connection is formed between the first current blocking layer and the first contact, and the non-ohmic connection between the first current blocking layer and the first contact extends up to 50 μm inward of an upper lateral side edge of the first contact.

6. The LED assembly of claim 1 wherein a non-ohmic connection is formed between the first current blocking layer and the first contact, and the non-ohmic connection between the first current blocking layer and the first contact extends up to 50 μm inward of a plurality of upper lateral side edges of the first contact.

7. The LED assembly of claim 1 wherein the first current blocking layer is between the LED and the first contact.

8. The LED assembly of claim 7 wherein the first current blocking layer comprises an insulating layer disposed between the first contact and the first layer.

9. The LED assembly of claim 8 wherein the insulating layer is transparent.

10. The LED assembly of claim 8 wherein the insulating layer comprises a material selected from SiO₂, Si₃O₄, Al₂O₃, and TiO₂.

11. The LED assembly of claim 1 wherein the first current blocking layer is formed in the first layer.

12. The LED assembly of claim 11 wherein the first current blocking layer is a plasma treated region of the first layer.

13. The LED assembly of claim 12 wherein the plasma treatment compensates a doping concentration of the first layer.

14. The LED assembly of claim 12 wherein the plasma treatment converts the conductivity type of the first layer to the opposite conductivity type.

15. The LED assembly of claim 12 wherein the plasma treatment uses a gas including O₂, N₂, H₂, Ar, He, Ne, Kr, Xe, or any combination thereof.

16. The LED assembly of claim 1 wherein the first current blocking layer surrounds a portion of the first layer and defines a portion of the light emitting layer that emits photons.

17. A vertical light emitting diode (LED) assembly comprising:
an LED comprising a light emitting layer disposed between a first layer having a first conductivity type and a second layer having a second conductivity type;
a substrate bonded to the LED;
a first contact disposed between the LED and the substrate, wherein the first contact is electrically coupled to the first layer; and
a first current blocking layer formed along a periphery of the LED at an interface with the first contact and covering a peripheral portion of the first contact.

18. The LED assembly of claim 17 wherein the first contact comprises a material having an optical reflectivity greater than 80%.

19. The LED assembly of claim 17 wherein the first contact comprises Ag.

20. The vertical LED assembly of claim 17 further comprising:
a second contact electrically coupled to the second layer; and
a second current blocking layer having a portion substantially aligned with the second contact at an interface with the LED and the first contact, wherein a non-ohmic connection is formed between the second current blocking layer and the first contact.

21. The vertical LED assembly of claim 17 wherein a non-ohmic connection is formed between the first current blocking layer and the first contact, and the non-ohmic connection between the first current blocking layer and the first contact extends up to 50 μm inward of an upper lateral side edge of the first contact.

22. The LED assembly of claim 17 wherein a non-ohmic connection is formed between the first current blocking layer and the first contact, and the non-ohmic connection between the first current blocking layer and the first contact extends up to 50 μm inward of a plurality of upper lateral side edges of the first contact.

23. The LED assembly of claim 17 wherein the first current blocking layer surrounds a portion of the first layer and defines a portion of the light emitting layer that emits photons.

24. A flip-chip light emitting diode (LED) assembly comprising:
an LED comprising a light emitting layer disposed between a first layer having a first conductivity type and a second layer having a second conductivity type;
a submount bonded to the LED;
a first contact disposed between the LED between the LED and the submount, wherein the first contact is electrically coupled to the first layer; and
a first current blocking layer formed along a periphery of the LED at an interface with the first contact and covering a peripheral portion of the first contact.

25. The LED assembly of claim 24 wherein the first contact comprises a material having an optical reflectivity greater than 80%.

26. The LED assembly of claim 24 wherein the first contact comprises Ag.

27. The flip-chip LED assembly of claim 24 further comprising:
a first interconnect electrically coupled to the first contact;
a second interconnect electrically coupled to the second layer;
a third interconnect and a fourth interconnect attached to the submount; and
wherein the first interconnect forms an electrical contact with the third interconnect, and the second interconnect forms an electric contact with the fourth interconnect.

28. The flip-chip LED assembly of claim 24 wherein a non-ohmic connection is formed between the first current blocking layer and the first contact, and the non-ohmic connection between the first current blocking layer and the first contact extends up to 50 μm inward of an upper lateral side edge of the first contact.

29. The LED assembly of claim 24 wherein a non-ohmic connection is formed between the first current blocking layer and the first contact, and the non-ohmic connection between the first current blocking layer and the first contact extends up to 50 μm inward of a plurality of upper lateral side edges of the first contact.

30. The LED assembly of claim 24 wherein the first current blocking layer surrounds a portion of the first layer and defines a portion of the light emitting layer that emits photons.
